(19) United States
(12) Patent Application Publication
(10) Pub. No.: US 2005/0248472 A1
(43) Pub. Date: Nov. 10, 2005

(54) Smart key exclusively for telephones calculator, remote controller and camera

(76) Inventor: Jung-Tsung Wei, Tainan City (TW)

Correspondence Address: NIKOLAI & MERSEREAU, P.A., 900 SECOND AVENUE SOUTH, SUITE 820, MINNEAPOLIS, MN, 55402, US

(21) Appl. No.: 10/840,913

(22) Filed: May 7, 2004

(51) Int. Cl. H03M 11/00; H03K 17/94

(52) U.S. Cl. 341/20

(57) ABSTRACT

This invention discloses a smart key exclusively for telephone, calculator, remote controller and camera, which comprises a recession having a sensor point disposed on a special instruction press key or at a local position of a press key, such that when a user's finger touches the desired press key, pr presses a predetermined position, or the force of the pressing finger drives the muscle into the recession, a sensing effect is produced with the finger. Therefore a predetermined signal is produced by the press key to achieve the control purpose for a predetermined function. Thus, the operation is not only gentle and easy, but also makes the signal produced by the press key a non-contact structure with the contact point. The press keys will not have oxidized contract points or poor contacts even after a long time of use.

### FIELD OF THE INVENTION

The present invention relates to a smart key, more particularly to a smart key exclusively designed for telephones, calculators, remote controllers and cameras, which has a touch control sensing capability and effect.

### BACKGROUND OF THE INVENTION

As we all know, telephones, calculators, remote controllers or cameras come with many press keys (as shown in FIGS. 1 to 5), and each press key has its predetermined operation control purpose and function, and most of the press keys have a press key 2 structure adopting a silica gel or a plastic material, and each press key at its bottom has an electric conductive section 21 made of an electrically conductive material, and a press key hole 10 for accommodating the press key 2 is disposed on a panel 1, and a circuit board 4 with a keyswitch prong 41 etched on its surface for triggering an electric connection is disposed correspondingly under the press key 2 (refer to FIGS. 6 to 8), therefore when the press key 2 is pressed, the electric conductive section 21 and the keyswitch prong 41 etched on the circuit board 4 are electrically connected to produce a predetermined signal to achieve the control of different functions.

The operation of such press key structure and its control method and procedure are described below:
1. A user aims a finger at the press key 2.
2. Move the finger to touch the press key 2.
3. Press the press key 2 down by the finger to a certain depth.
4. Draw the finger back to release the force exerted by the finger.
5. Exit the press key 2.

Therefore, the operation of the foregoing press key 2 requires a finger to exert force on the press key 2; although the exerting force is not large, yet it requires a force to certain extent. If the exerting force and the depth of the press are not sufficient, it is unable to electrically connect the electric conductive section 21 and the keyswitch prong 41 on the circuit board 4. As a result, the dialup or control signal cannot be produced. On the other hand, if the exerting force is too large, it will cause abrasions and damages to the electric conductive section 21 and the keyswitch prong 41 or even will produce sparks due to the instant electric connection, which will shorten the life of the press key 2. Further, the larger the force pressing on the press key 2, the larger is the friction between the finger and the press key 2, so that the numerals, text, patterns, or symbols printed on the surface of the press key 2 will be worn away easily

Further, since the press key 2 is embedded in the press key hole 10 on a panel 1, the press key hole 10 is slightly larger than the press key 2 for allowing the press key 2 to move nimbly, but it also tilts the press key 2 when a finger presses on the press key 2 and its force exerting point is not located at the central position. As a result, the electric conductive section 21 is unable to contact evenly in parallel with the keyswitch prong 41 and causes a poor connection and the dialup or control signal cannot be produced.

Further, after the electric conductive section 21 at the bottom of the press key 2 or the keyswitch 41 has been used for a long time, it is very easy to have the oxidation causing a poor contact between the two. Therefore, it is very common that a remote control signal cannot be sent even when a user exerts a large force on the press key 2.

In addition, when the press key of this structure is used on a camera, the camera will be shaken easily due to the force exerted by a finger on the press key, and thus affecting the quality of the photographs.

### SUMMARY OF THE INVENTION

To improve the shortcomings of having a poor contact or a short life caused by an easily oxidation of a contact-type contact point of the foregoing prior-art press key and requiring larger for the operation, the present invention provides the press key a capability of sensing a touch or an approach of a finger to the press key, so that the press key becomes a touch control sensing press key without contact points, and makes the operation of the press keys lighter and easier. Oxidized contact points or poor contacts will not happen at all even the press keys are used and pressed for a long time. Meanwhile, to meet the requirements of the applications for different occasions, the press key may be designed to have the sensing effect on a partial area of the press key, or having the partial sensing area disposed at a lower section of the press key in order to prevent users from pressing a press key by mistake.

Therefore, the technological measure adopted to achieve the foregoing objective of the present invention is to connect a touch control sensing circuit to the press keys of a telephone, a calculator, a remote controller or a camera, and makes the press key as a sensor.

Further, the foregoing press keys can be designed to have the sensing effect on a predetermined partial area of the press keys.

The partial sensing area of the foregoing press keys can be a recession disposed at a lower section of the press key and having a contact point, or a protrusion having a recession with a sensing point disposed at a lower section of the press key.

The detailed description and technical characteristics of the present invention are described together with the drawings as follows.

### BRIEF DESCRIPTION OF THE DRAWINGS

FIG. 1 is a perspective view of a conventional telephone.

FIG. 2 is a perspective view of a conventional mobile telephone.

FIG. 3 is a perspective view of a conventional remote controller.

FIG. 4 is a perspective view of a conventional calculator.

FIG. 5 is a perspective view of a conventional camera.

FIG. 6 is a cross-sectional view of a conventional press key.

FIG. 7 is an illustrative view of a circuit layout of a conventional press key triggering circuit board.

FIG. 8 is an illustrative view of a conventional press key being pressed and tilted.

FIG. 9 is an illustrative view of the structure of the press key according to a first preferred embodiment of the present invention.

FIG. 10 is an illustrative view of the structure of the press key according to a second preferred embodiment of the present invention.

FIG. 11 is an illustrative view of the structure of the press key according to a third preferred embodiment of the present invention.

FIG. 12 is an illustrative view of the structure of the press key according to a fourth preferred embodiment of the present invention.

FIG. 13 is an illustrative view of the structure of the press key according to a fifth preferred embodiment of the present invention.

FIG. 14 is an illustrative view of the press key before the user's finger is pressed on the press key according to a sixth preferred embodiment of the present invention.

FIG. 15 is an illustrative view of the press key after the user's finger is pressed on the press key according to a sixth preferred embodiment of the present invention.

FIG. 16 is an illustrative view of the press key according to a seventh preferred embodiment of the present invention.

FIG. 17 is an illustrative view of the operation of the press key according to an eighth preferred embodiment of the present invention.

FIG. 18 is an illustrative view of the structure of the press key according to a ninth preferred embodiment of the present invention.

FIG. 19 is an illustrative view of a mobile phone having a cover according to the present invention.

FIG. 20 is an illustrative view of a remote control having a cover according to the present invention.

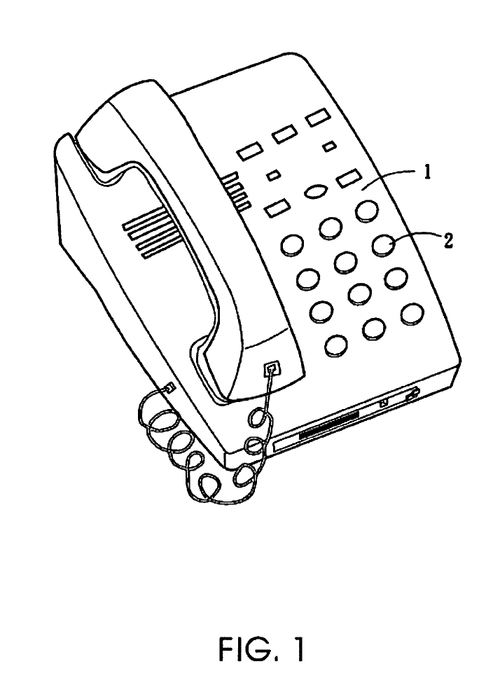

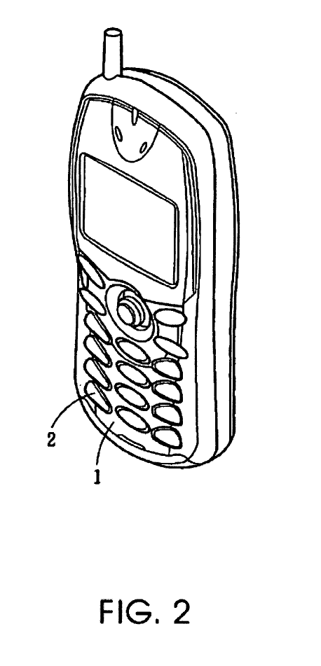

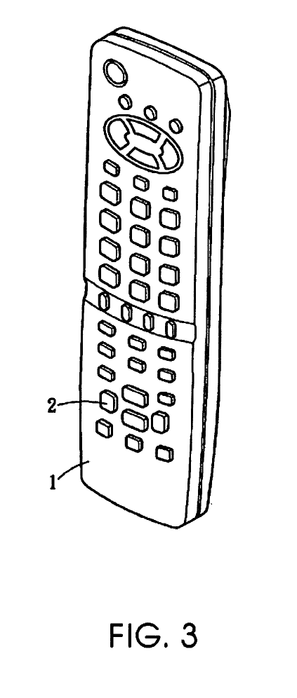

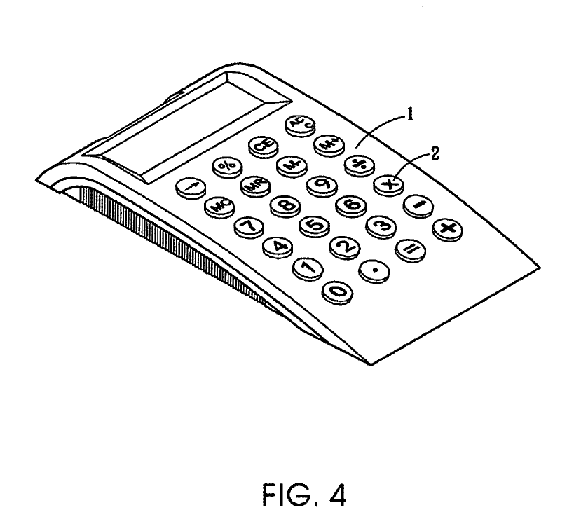

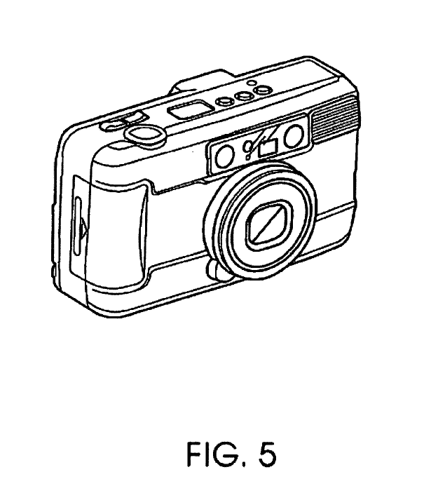

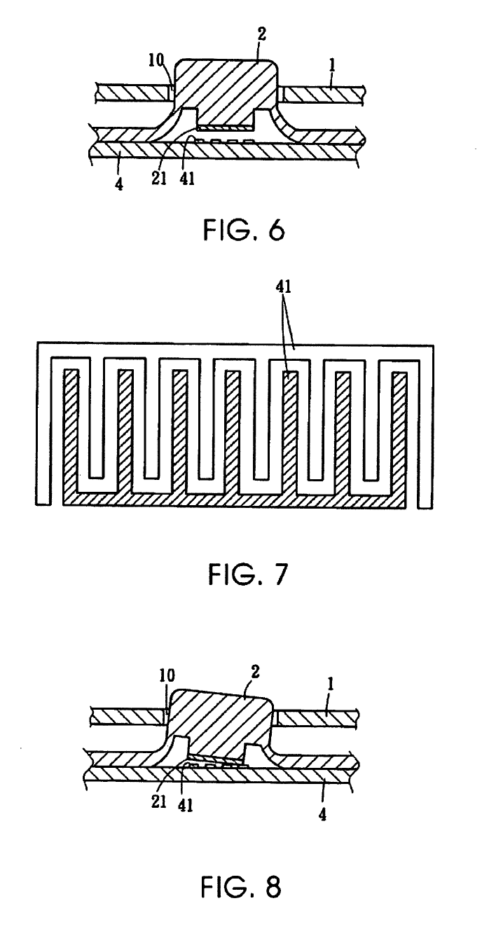

### DETAILED DESCRIPTION OF THE PREFERRED EMBODIMENTS

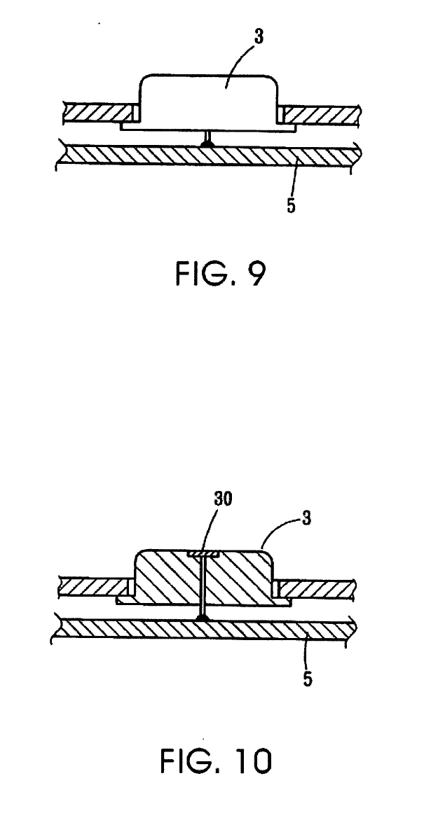

Please refer to FIG. 9 for each press key 3 exclusively designed for a telephone, a calculator, a remote controller (such as a remote controller for an electric appliance, an iron rolling door, or a motor vehicle) and a camera, which is coupled to a touch control sensing circuit 5 and makes each press key 3 as a sensor and each press key 3 has the touch control sensing or approach sensing effect and capability. Therefore, if a user touches or approaches the press key 3, the press key can sense such action and produce a signal. Such signal is provided to a control circuit to achieve the expected control purpose.

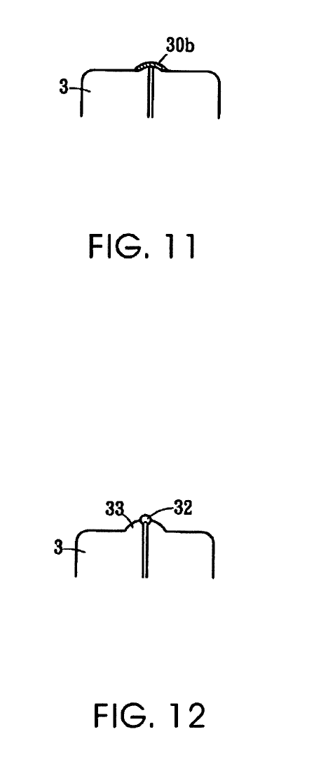

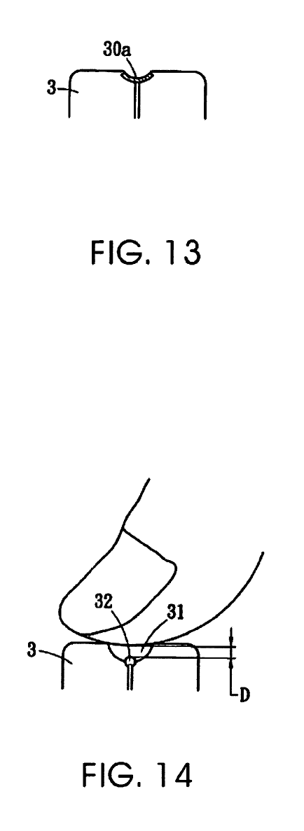

Further, the whole piece of foregoing press key 3 as shown in FIG. 10 has the sensing effect, but the sensing effect can be set by designing a sensing section 30 of a smaller area coupled to the touch control sensing circuit 5 at a predetermined position of the press key 3, so that only the sensing section 30 has the sensing effect. Alternatively, the sensing section 30b is substantially in a convexly curved shape as shown in FIG. 11, or a curved protrusion 33 is disposed at the center of the press key 3 as shown in FIG. 12, or a sensing point 32 disposed at the center of the curved protrusion 33. Of course, the sensing section 30a could be substantially in a concavely curved shape as shown in FIG. 13. The foregoing embodiments are different structural method incorporating a sensing surface or a sensing point in hope of providing different sensing positions with different structural configuration on the press key 3, and thus can meet the requirements for different occasions.

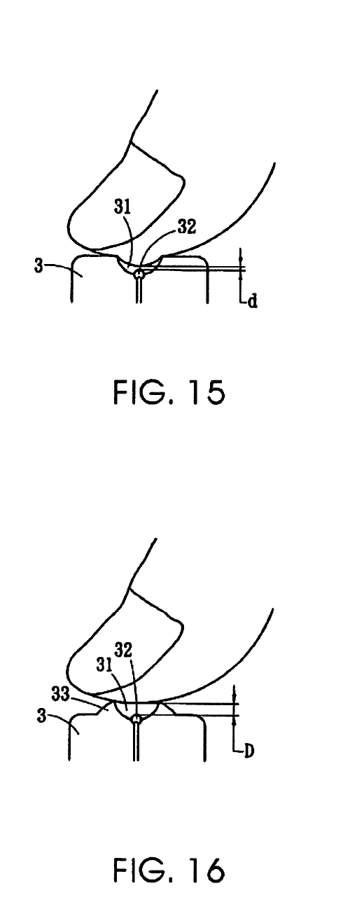

Further, the press key 3 as shown in FIG. 14 comprises a recession 31 disposed at the center of its top surface and a sensing point 32 disposed at a lower section in the middle of the recession 31, so that the sensing point 32 is coupled onto the touch control sensing circuit to make each press key 3 as a press key having the sensing effect and further as a touch control sensing press key without a contact point. Therefore, when a finger or a palm or any other part of muscle touches the press key 3, the muscle keeps an appropriate distance from the sensing point 32 in the recession 31 since the finger or the palm has not pressed on the press key 3. As a result, the sensing effect does not occur. However, if a finger slightly presses on the press key 3 as shown in FIG. 15, then the muscle of the finger sinks into the recession 31 so that the muscle gets even close or touches the sensing point 32 to drive the sensing point 32 to produce a predetermined signal and achieve the desired control objective.

Therefore, a non-contact point type touch control sensing press key 3 for a telephone, a calculator or a remote controller not only provides a light and easy operation of the press keys, but also greatly reduces the vibration of a camera when the such press key 3 is used for the operation of the camera and the shutter of a camera adopts such touch control sensing press key. Meanwhile, the press key 3 after being operated and pressed for a long time does not have the problems of having oxidized contact points or poor contacts.

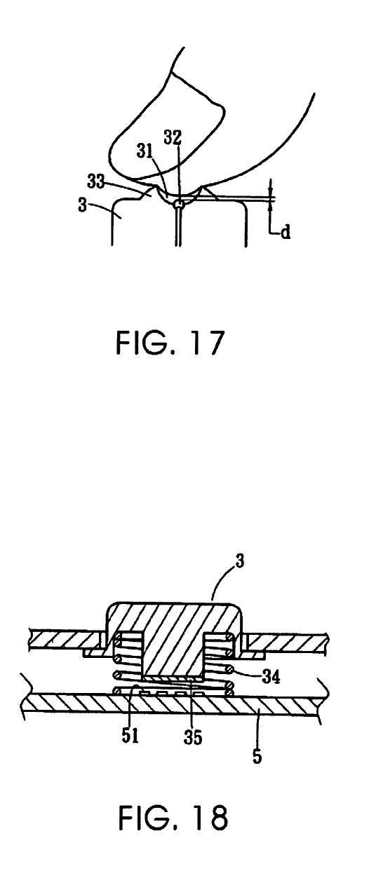

Further, the press key 3 comprises a protrusion 33 disposed in the middle of the press key 3 and a sensing point 32 disposed at a lower section in the middle of the recession 31 as shown in FIGS. 16 and 17. Similarly, if the user's finger gently presses on the press key 3, the muscle of the finger will get closer to the sensing point 32 or will touch the sensing point 32 to produce a predetermined control signal.

The recession 31 of the press key 3 as shown in FIGS. 14 and 16 can be designed as the sensing section 30a as shown in FIG. 13, so that the recession 31 can have the sensing capability. Therefore the recession 31 and the sensing point 32 can simultaneously have the sensing effect for a touch or an approach to the key switch.

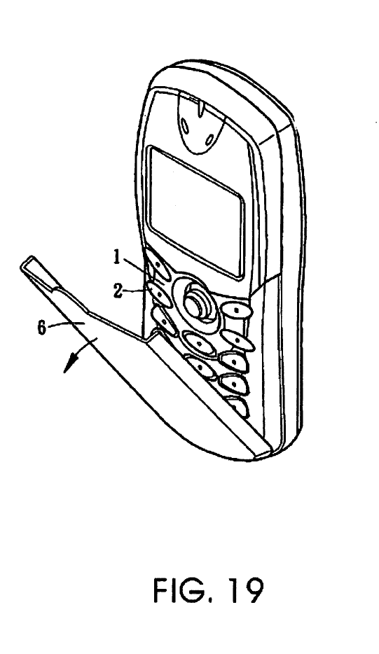

In FIG. 18, the press key 3 is supported by a resilient member 34, and the lower section of the resilient member 34 is coupled with the touch control sensing circuit 5, and a keyswitch prong 51 is disposed on the touch control sensing circuit 5 corresponding to the press key 3, and an electric conductive section 35 is disposed at the lower section of the press key 3 to produce a touch control sensing effect when a user touches the press key 3. The press key 3 has the resilient pressing texture similar to that of a traditional press key. Meanwhile, if the touch control sensing capability of the press key 3 is lost, or when a press key 3 is pressed by a finger, the electric conductive section 35 will touch the keyswitch prong 51 on the touch control sensing circuit 5, so that the press key 3 still maintains the control functions of the traditional press key. Therefore, the press key 3 concurrently has the sensing type and the contact type control functions, and the sensing type or contact type control function of the press key 3 can be selected by a switch. As a result, the press key 3 can be set as a sensing type press key, a contact type press key, or both.

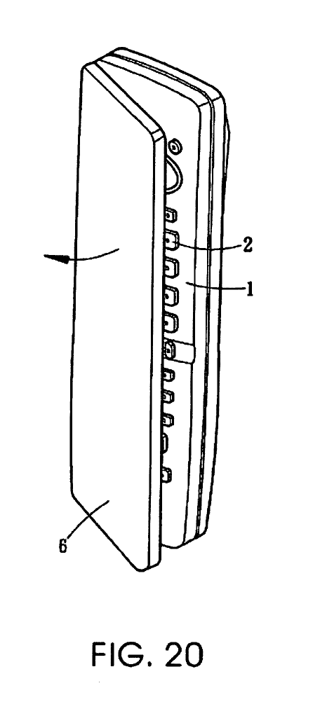

To prevent the sensing type press key according to the present invention from being touched by accident in some special occasions, a cover 6 is set to cover the panel of the press keys as shown in FIGS. 19 and 20.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

1. A smart key exclusively for telephone, calculator, remote controller and camera, comprising a plurality of press keys each being coupled to a sensor control circuit for providing a sensor effect, thereby said press key becoming a sensor for a touch control sensing press key having no contact point.

2. The smart key exclusively for telephone, calculator, remote controller and camera of claim 1, wherein said press key comprises a sensing section disposed in a predetermined small area in the middle of a top surface of said press key such that said sensing section has a sensing capability.

3. The smart key exclusively for telephone, calculator, remote controller and camera of claim 1, wherein said press key comprises a sensing section disposed in a predetermined small area in the middle of a top surface of said press key and said sensing section is substantially in a shape selected from a collection of a flat shape, a concavely curved shape, and a convexly curved shape.

4. The smart key exclusively for telephone, calculator, remote controller and camera of claim 1, wherein said press key selectively comprises a protrusion and a recession disposed in the middle of a top surface of said press key, and a sensing point disposed in the middle of said selectively protrusion and recession.

5. The smart key exclusively for telephone, calculator, remote controller and camera of claim 1, wherein said press key comprises a protrusion disposed in the middle of a top surface of said press key, a recession disposed on top of said protrusion and a sensing point disposed in the middle of said recession.

6. The smart key exclusively for telephone, calculator, remote controller and camera of claim 1, wherein said recession and said sensing point simultaneously have a sensing capability.

7. The smart key exclusively for telephone, calculator, remote controller and camera of claim 5, wherein said press key selectively comprises a plurality of said sensor sections and a plurality of said sensor points.

8. The smart key exclusively for telephone, calculator, remote controller and camera of claim 5, wherein said press key adopts a transitional resilient press key, and said press key has a touch-control sensing capability.

9. The smart key exclusively for telephone, calculator, remote controller and camera of claim 5, wherein said press key comprises a top surface in a shape selected from a collection of a plat shape, a convexly curved shape and a concavely curved shape.

10. The smart key exclusively for telephone, calculator, remote controller and camera of claim 2, wherein said press key selectively comprises a plurality of said sensor sections and a plurality of said sensor points.

11. The smart key exclusively for telephone, calculator, remote controller and camera of claim 2, wherein said press key adopts a transitional resilient press key, and said press key has a touch-control sensing capability.

12. The smart key exclusively for telephone, calculator, remote controller and camera of claim 2, wherein said press key comprises a top surface in a shape selected from a collection of a plat shape, a convexly curved shape and a concavely curved shape.

13. The smart key exclusively for telephone, calculator, remote controller and camera of claim 1, wherein said press key adopts a transitional resilient press key, and said press key has a touch-control sensing capability.

14. The smart key exclusively for telephone, calculator, remote controller and camera of claim 1, wherein said press key comprises a top surface in a shape selected from a collection of a plat shape, a convexly curved shape and a concavely curved shape.

15. The smart key exclusively for telephone, calculator, remote controller and camera of claim 4, wherein said press key adopts a transitional resilient press key, and said press key has a touch-control sensing capability.

16. The smart key exclusively for telephone, calculator, remote controller and camera of claim 4, wherein said press key comprises a top surface in a shape selected from a collection of a plat shape, a convexly curved shape and a concavely curved shape.

17. The smart key exclusively for telephone, calculator, remote controller and camera of claim 4, wherein said press key selectively comprises a plurality of said sensor sections and a plurality of said sensor points.
